(19) United States
(12) Patent Application Publication
(10) Pub. No.: US 2006/0177968 A1
(43) Pub. Date: Aug. 10, 2006

(54) Method for fabricating semiconductor packages with semiconductor chips

(75) Inventor: Shih-Ping Hsu, Hsin-chu (TW)

Correspondence Address: CLARK & BRODY, 1090 VERMONT AVENUE, NW, SUITE 250, WASHINGTON, DC, 20005, US

(73) Assignee: Phoenix Precision Technology Corporation

(21) Appl. No.: 11/200,009

(22) Filed: Aug. 10, 2005

(30) Foreign Application Priority Data
Feb. 5, 2005 (TW) 094103968

(51) Int. Cl. H01L 23/02; H01L 21/50; H01L 21/48; H01L 21/44

(52) U.S. Cl. 438/110

(57) ABSTRACT

A method for fabricating semiconductor packages with semiconductor chips includes: providing a reel tape capable of being rolled up, the reel tape for accommodating at least one row of carriers; mounting at least one semiconductor chip in each of the carriers, wherein a plurality of electrode pads are provided on an upper surface of the semiconductor chip; and forming a dielectric layer and a circuit layer on each set of the carriers and the semiconductor chips, wherein the circuit layer is electrically connected to the electrode pads of the semiconductor chip, so as to package the semiconductor chip in each of the carriers to form a package. The above method can continuously fabricate packages, and prevent imprecise positional alignment on a large carrier panel, as well as avoid the necessity of fabricating conductive bumps on the semiconductor chip for electrical connection, such that the fabrication costs can be reduced.

### FIELD OF THE INVENTION

The present invention relates to methods for fabricating semiconductor packages, and more particularly, to a method for fabricating semiconductor packages with semiconductor chips by using a reel tape having carriers.

### BACKGROUND OF THE INVENTION

Carriers for mounting semiconductor chips thereon in semiconductor packages may be classified into lead frame and substrate, according to connection structures thereof for connecting with external devices. In the case of using a lead frame that is formed of a metal sheet by stamping, a chip is attached to a lead frame and is electrically connected to the lead frame by wire-bonding technology, and then an encapsulant is formed to encapsulate the lead frame and the chip, such that a lead-frame-based semiconductor package is fabricated. However, such lead-frame-based semiconductor package usually has a relatively larger volume and a limited number of input/output (I/O) contacts, thereby not fulfilling the package requirements of being light, thin and small in profile. Therefore, in portable electronic products, the lead-frame-based semiconductor package has gradually been replaced by a substrate-based semiconductor package having high-density arrangement of I/O contacts. The substrate-based semiconductor package has a relatively thinner and smaller profile, and thus has become a mainstream package product.

In a fabrication method of the substrate-based semiconductor package, a substrate module plate for carrying chips thereon is firstly manufactured and is then cut into a plurality of single substrates. The substrates are subsequently sent to a package factory to be performed with die-bonding, electrically connecting and encapsulating processes. Since fabrication of the substrates is independent from the fabrication of semiconductor packages, investments in manufacturing equipment are very huge and thus cause an increase in production costs.

The types of electrical connection between the chip and the substrate include flip-chip type connection and wire-bonding type connection. For the flip-chip type connection, the chip is formed with conductive bumps thereon, and the substrate is formed with corresponding pre-solder bumps thereon, such that the chip is electrically connected to the substrate by bonding the conductive bumps of the chip to the corresponding pre-solder bumps of the substrate. Since the substrate and the chip need to be formed with the pre-solder bumps and the conductive bumps for use in electrical connection respectively, the structure is complicated and the costs are increased. Further since the conductive bumps of the chip should be accurately aligned with the pre-solder bumps of the substrate, this reduces the yields and increases the overall fabrication costs.

Another fabrication method for fabricating a semiconductor package is to directly form a build-up circuit structure on a chip that has been attached to a substrate, without forming the foregoing conductive bumps and pre-solder bumps. This fabrication method may be carried out using a single panel comprising a plurality of substrates. However, it is very difficult to perform alignment on the panel to form the build-up circuit structure since fabrication of the build-up circuit structure needs very high accuracy. Although such fabrication method is productive, when performing alignment with high accuracy, manufacturing equipment having improved alignment capability is required correspondingly. As it is necessary to adopt the manufacturing equipment with higher accuracy and better performance, the equipment costs are increased. Moreover, by the fabrication method, the panel should be inspected and aligned one by one during the manufacturing processes, and thus manufacturing equipment with better alignment performance is required, thereby further increasing the equipment costs.

Therefore, the problem to be solved here is to develop a method for fabricating semiconductor packages so as to overcome the foregoing drawbacks.

### SUMMARY OF THE INVENTION

In view of the foregoing drawbacks in the conventional technology, an objective of the present invention is to provide a method for continuously fabricating semiconductor packages with semiconductor chips.

Another objective of the present invention is to provide a method for fabricating semiconductor packages with semiconductor chips, which can avoid a problem of imprecise positional alignment on a large carrier panel.

Still another objective of the present invention is to provide a method for fabricating semiconductor packages with semiconductor chips, without fabricating conductive bumps on a chip and pre-solder bumps on a substrate.

A further objective of the present invention is to provide a method for fabricating semiconductor packages with semiconductor chips, which can reduce the material costs.

In accordance with the above and other objectives, according to a preferred embodiment of the present invention, the method for fabricating semiconductor packages with semiconductor chips comprises the steps of: providing a reel tape capable of being rolled up; attaching at least one row of carriers to the reel tape; mounting at least one semiconductor chip in each of the carriers, wherein a plurality of electrode pads are provided on an upper surface of the semiconductor chip; and forming a dielectric layer and a circuit layer on each set of the carriers and the semiconductor chips, wherein the circuit layer is electrically connected to the electrode pads of the semiconductor chip.

By attaching the at least one row of carriers to the reel tape and mounting the semiconductor chips in the carriers to form semiconductor packages, the semiconductor packages can be fabricated continuously and a problem of imprecise positional alignment on a large carrier panel is avoided.

By the continuous fabrication of semiconductor packages, loading/unloading operations are not required, thereby simplifying the operational procedures and increasing the production speed.

Further since the loading/unloading operations are not required for the continuous fabrication of semiconductor packages by using the reel tape, an inconvenient alignment operation is not necessary, thereby reducing investments in manufacturing equipment with high performance and costs on the manufacturing equipment.

Each of the carriers is formed with at least one cavity therein, such that the semiconductor chip is received in the cavity of each of the carriers, and a build-up circuit structure can be directly formed on each set of the carriers and the semiconductor chips, without having to form bonding wires for wire-bonding type connection or fabricate conductive bumps and pre-solder bumps for flip-chip type connection. Thus, the materials used and costs thereof are reduced in the present invention.

### BRIEF DESCRIPTION OF THE DRAWINGS

The present invention can be more fully understood by reading the following detailed description of the preferred embodiments, with reference made to the accompanying drawings, wherein:

FIGS. 1A and 1B are respectively a side view and a top view showing a reel tape used in a method for fabricating semiconductor packages with semiconductor chips according to the present invention;

FIGS. 2A to 2D are partially cross-sectional views showing procedures of the method for fabricating semiconductor packages with semiconductor chips according to the present invention;

FIG. 3 is a cross-sectional view showing continuous procedures of the method for fabricating semiconductor packages with semiconductor chips according to the present invention; and

FIG. 4 is a cross-sectional view showing a semiconductor package fabricated by the method according to another preferred embodiment of the present invention.

### DETAILED DESCRIPTION OF THE PREFERRED EMBODIMENTS

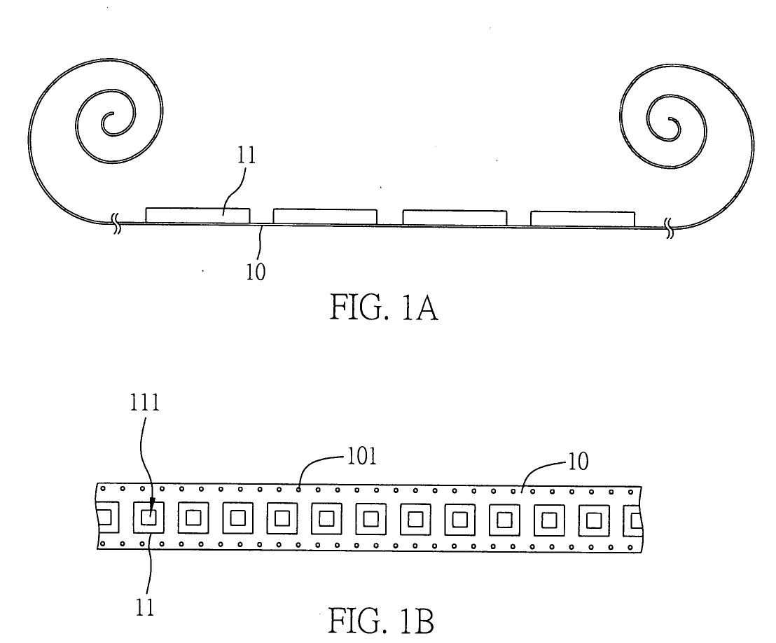

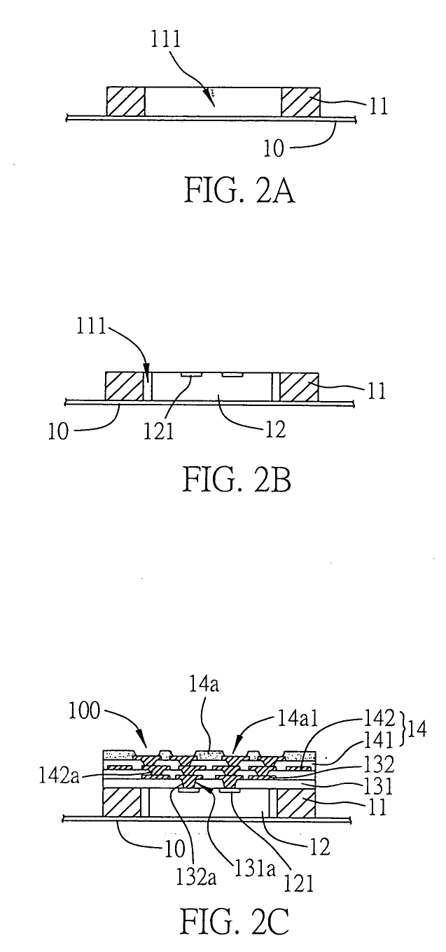

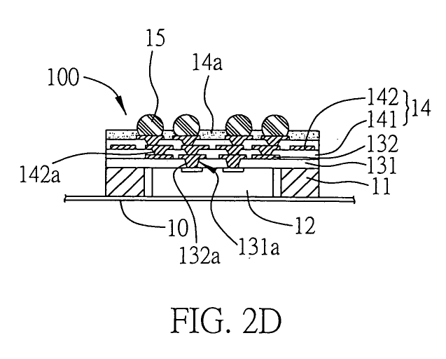

Referring to FIGS. 1A-1B and 2A-2D, a preferred embodiment of a method for fabricating semiconductor packages with semiconductor chips according to the present invention is illustrated.

As shown in FIGS. 1A and 1B, a reel tape 10 such as a roll film is provided, wherein both ends of the reel tape 10 can be rolled up respectively, and the reel tape 10 is fed from one roll toward the other roll. Moreover, sprocket holes 101 are formed at both sides of the reel tape 10, such that the reel tape 10 can be intermittently and joggingly fed by an intermittent mechanism (not shown).

As shown in FIG. 2A, at least one row of carriers 11 are attached to the reel tape 10 (only one carrier 11 is shown), wherein each of the carriers 11 is formed with a cavity 111. The carrier 11 can be a metal plate, a circuit board, a substrate with a circuit layer, or an insulating plate.

As shown in FIG. 2B, a semiconductor chip 12 is mounted in each of the carriers 11 (only one carrier 11 is shown), wherein an upper surface of the semiconductor chip 12 is provided with a plurality of electrode pads 121. The semiconductor chip 12 may be, for example, an active device such as an IC (integrated circuit) chip, or a passive device such as a capacitor or a resistor. The semiconductor chip 12 is received in the cavity 111 of each of the carriers 11.

As shown in FIG. 2C, a dielectric layer 131 and a patterned circuit layer 132 are formed over the carrier 11 and the semiconductor chip 12, wherein the electrode pads 121 of the semiconductor chip 12 are electrically connected to the patterned circuit layer 132, so as to package the semiconductor chip 12 in the carrier 11 to form a semiconductor package 100. Specifically, the dielectric layer 131 is firstly formed over the carrier 11 and the semiconductor chip 12. Then, a plurality of openings 131a are formed in the dielectric layer 131 by for example laser drilling or plasma etching if the dielectric layer 131 is photoinsensitive, or by for example exposing and developing if the dielectric layer 131 is photosensitive, so as to expose the electrode pads 121 of the semiconductor chip 12 and a portion of the carrier 11 (if the carrier 11 is a substrate with a circuit layer) from the dielectric layer 131. Next, the patterned circuit layer 132 is formed on the dielectric layer 131, and electrically conductive structures 132a are formed in the openings 131a of the dielectric layer 131, such that the patterned circuit layer 132 is electrically connected to the electrode pads 121 of the semiconductor chip 12 via the electrically conductive structures 132a. The electrically conductive structures 132a may be electrically conductive blind vias or bumps, and the like.

A circuit build-up process may be subsequently performed to form at least one build-up circuit structure 14 over the dielectric layer 131 and the circuit layer 132. The build-up circuit structure 14 comprises a dielectric layer 141, a circuit layer 142 formed on the dielectric layer 141, and electrically conductive blind vias 142a penetrating the dielectric layer 141, for electrically connecting the circuit layer 142 to the circuit layer 132.

Next, a solder mask layer 14a may be formed on an outer surface of the build-up circuit structure 14, wherein the solder mask layer 14a is provided with a plurality of openings 14a1 for exposing portions of a circuit layer formed on the outer surface of the build-up circuit structure 14.

As shown in FIG. 2D, a plurality of electrically conductive elements 15 for electrically connecting the circuit layer 142 to an external device are formed at the openings 14a1 of the patterned solder mask layer 14a on the build-up circuit structure 14. The electrically conductive elements 15 are, for example, electrically conductive studs, metal pads, or solder balls.

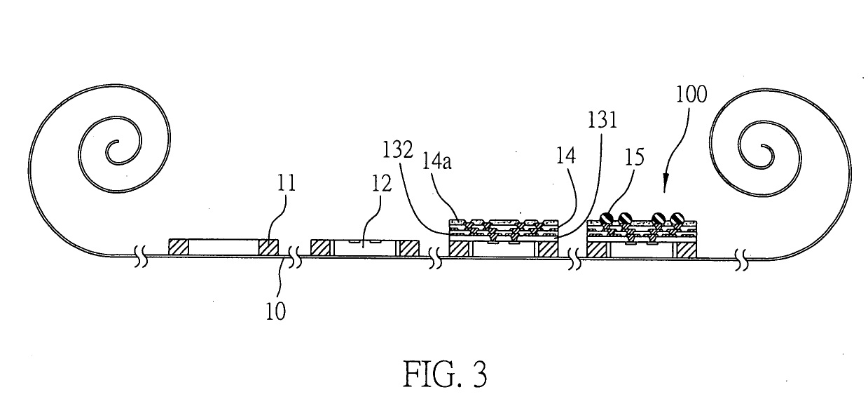

FIG. 3 is a cross-sectional view showing continuous procedures of the method for fabricating semiconductor packages with semiconductor chips according to the present invention. Referring to FIG. 3, the reel tape 10 passes through manufacturing apparatuses for various processes (namely, the manufacturing apparatuses for various processes are connected in series with the reel tape 10), such that the various processes can be performed on the reel tape 10 in sequence. The semiconductor packages 100 may be continuously fabricated in one row on the reel tape 10, or may be continuously fabricated in parallel rows, or may be partially continuously fabricated, thereby preventing the inconvenience of loading/unloading large carrier panels as in the conventional fabrication method. According to the present invention, since the semiconductor packages can be continuously fabricated, and the number of alignment operations in the manufacturing apparatuses can be greatly reduced, the production speed is increased and the necessity of adopting expensive manufacturing equipment with high alignment performance is avoided, thereby reducing production costs and equipment costs.

After completing packaging and implanting the electrically conductive elements 15 for the semiconductor packages 100, the reel tape 10 is cut to form a plurality of independent semiconductor packages 100.

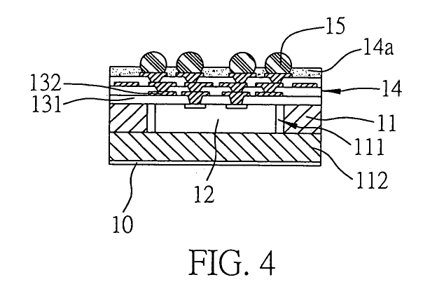

FIG. 4 is a cross-sectional view showing a semiconductor package fabricated by the method according to another preferred embodiment of the present invention. Referring to FIG. 4, a heat spreader 112 may be provided on a bottom surface of the carrier 11 and attached to the reel tape 10. The carrier 10 is formed with the cavity 111. therein, and the semiconductor chip 12 is received within the cavity 111 and attached to the heat spreader 12. Similarly, as described-above, the dielectric layer 131 and the circuit layer 132 are formed over the carrier 11 and the semiconductor chip 12, and the build-up circuit structure 14 and the electrically conductive elements 15 are formed over the dielectric layer 131 and the circuit layer 132. According to this embodiment, heat generated by the semiconductor chip 12 can be dissipated out of the semiconductor package via the heat spreader 112.

The invention has been described using exemplary preferred embodiments. However, it is to be understood that the scope of the invention is not limited to the disclosed embodiments. On the contrary, it is intended to cover various modifications and similar arrangement. The scope of the claims therefore should be accorded the broadest interpretation so as to encompass all such modifications and similar arrangements.

What is claimed is:

1. A method for fabricating semiconductor packages with semiconductor chips, comprising the steps of:
providing a reel tape capable of being rolled up;
attaching at least one row of carriers to the reel tape;
mounting at least one semiconductor chip in each of the carriers, wherein a plurality of electrode pads are provided on an upper surface of the semiconductor chip; and
forming a dielectric layer and a circuit layer on each set of the carriers and the semiconductor chips, wherein the circuit layer is electrically connected to the electrode pads of the semiconductor chip.

2. The method of claim 1, wherein sprocket holes are formed at both sides of the reel tape.

3. The method of claim 1, wherein the reel tape is a roll film.

4. The method of claim 1, wherein the carrier is provided with a cavity therein.

5. The method of claim 4, wherein the semiconductor chip is received in the cavity of the carrier.

6. The method of claim 4, wherein the carrier is one of a metal plate, a circuit board, a substrate with a circuit layer thereon, and an insulating plate.

7. The method of claim 6, wherein a heat spreader is attached to a bottom surface of the carrier.

8. The method of claim 1, further comprising the step of:
forming, at least one build-up circuit structure on the dielectric layer and the circuit layer.

9. The method of claim 8, wherein the build-up circuit structure comprises a dielectric layer, a circuit layer formed on the dielectric layer, and electrically conductive blind vias penetrating the dielectric layer, for electrically connecting the circuit layer of the build-up circuit structure to the circuit layer formed on each set of the carriers and the semiconductor chips.

10. The method of claim 9, further comprising the step of:
forming a patterned solder mask layer on a surface of the circuit layer of the build-up circuit structure.

11. The method of claim 10, further comprising the step of:
forming a plurality of electrically conductive elements at the patterned solder mask layer, wherein the electrically conductive elements are electrically connected to the circuit layer of the build-up circuit structure.

12. The method of claim 11, wherein the electrically conductive element is one of an electrically conductive stud, a metal pad, and a solder ball.

13. The method of claim 1, further comprising the step of:
cutting the reel tape to form a plurality of independent semiconductor packages.
